(19) United States
(12) Patent Application Publication
(10) Pub. No.: US 2010/0124334 A1
(43) Pub. Date: May 20, 2010

(54) AMPLIFICATION CIRCUIT AND AUDIO OUTPUT EQUIPMENT

(75) Inventors: Eriko Nonaka, Kanagawa-ken (JP); Katsuhiko Nakano, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/612,829

(22) Filed: Nov. 5, 2009

(30) Foreign Application Priority Data
Nov. 14, 2008 (JP) 2008-292029

(51) Int. Cl. H04R 5/00; H03F 99/00; H03F 3/68

(52) U.S. Cl. 381/28; 381/120; 330/124 R

(57) ABSTRACT

An amplification circuit and an audio output equipment provided with same are disclosed. The amplification circuit is provided with first, second and third amplifiers and an inverter. The first amplifier amplifies a first audio signal and outputs a first output signal. The inverter inverts a second audio signal and outputs an inverted signal. The second amplifier amplifies the inverted signal and outputs a second output signal. The third amplifier outputs a reference voltage corresponding to a central voltage of the amplitude of the first and the second output signals.

### CROSS REFERENCE TO RELATED APPLICATION

This application is based upon and claims the benefit of priority from the prior Japanese Patent Application No. 2008-292029, filed on Nov. 14, 2008, the entire contents of which are incorporated herein by reference.

### FIELD OF THE INVENTION

This invention relates to an amplification circuit to amplify an audio signal and to an audio output equipment provided with an amplification circuit.

### DESCRIPTION OF THE BACKGROUND

Many of car audio systems employ an audio output equipment of a BTL (Bridged Tied Load) connection system. The audio output equipment drives one speaker with two amplifiers. The two amplifiers are first and second amplifiers composing an amplification circuit. The first amplifier amplifies a non-inverted signal of an audio signal. The second amplifier amplifies an inverted signal of the audio signal. The first amplifier is connected to a terminal of the speaker, while the second amplifier is connected to another terminal of the speaker.

The potential difference is 2Vo between the terminals of the speaker, when the output voltage of the first amplifier is +Vo, and the output voltage of the second amplifier is −Vo. An output power Pout, which is generated between both ends of a load resistance of the speaker, is expressed by the following formula where the load resistance is RL.

Pout=(2Vo)²/RL=4Vo²/RL

The output of the BTL connection system is four times the output of an audio output equipment which drives one speaker with one amplifier.

When two speakers are used to receive stereo audio signals for two right and left channels One amplification circuit of such a BTL connection system needs four amplifiers totally, in order to connect two amplifiers to each of two speakers to output stereo audio signals for two right and left channels. The car audio systems are required to be installed in a limited space. Therefore, the size of a semiconductor chip of the amplification circuit becomes large since the semiconductor chip contains the four amplifiers.

On the other hand, an audio output equipment of a SEPP (Single Ended Push Pull) connection system is also known. The audio output equipment drives one speaker with one amplifier. In the SEPP connection system, an amplifier is connected to a terminal of a speaker, and another terminal of the speaker is connected to a ground terminal.

Though the output power of the SEPP connection system is inferior to that of the BTL connection system, the former system performs less power consumption because the former system contains a smaller number of amplifiers.

Japanese Patent Application Publication No. 2001-168658 (PP. 3-4, FIG. 1) discloses an audio output equipment which is provided with a BTL connection system and a SEPP connection system together. In the audio output equipment, the BTL connection system and the SEPP connection system are switched according to the levels of an input audio signal. During a low output mode of the audio output equipment, the SEPP connection system is used to drive a speaker in order to reduce power consumption of the audio output equipment.

However, the audio output equipment disclosed in the patent publication needs to have four amplifiers for two right and left channels to be used for the BTL connection system. The size of a semiconductor chip of the audio output equipment is not reduced, because the four amplifiers are formed on the semiconductor chip as in the audio output equipment which is provided with only a BTL connection system.

In order to make a chip size of an amplification circuit smaller, an audio output equipment containing amplification circuit may be composed of a SEPP connection system. When the amplification circuit is operated by a single power supply, an audio signal of the audio output equipment varies up and down with an intermediate voltage of the power supply centered.

A capacitor is needed to be inserted between an output terminal of the amplification circuit and a terminal of a speaker to remove direct current ingredient, for the purpose of performing an alternating current drive of the speaker. As a result, the audio output equipment becomes complicated. The cost of the audio output equipment rises as a whole.

### SUMMARY OF THE INVENTION

An aspect of the present invention provides an amplification circuit including a first amplifier to amplify a first audio signal and to output a first output signal, an inverter to invert a second audio signal and to output an inverted signal, a second amplifier to amplify the inverted signal and to output a second output signal, and a third amplifier to output a reference voltage corresponding to a central voltage of the amplitude of the first and the second output signals.

Another aspect of the present invention provides an audio output equipment including a first amplifier to amplify a first audio signal and to output a first output signal, an inverter to invert a second audio signal and to output an inverted signal, a second amplifier to amplify the inverted signal and to output a second output signal, a third amplifier to output a reference voltage corresponding to a central voltage of the amplitude of the first and the second output signals, and first and second speakers, wherein an output terminal of the first amplifier is connected to a terminal of a first polarity provided at the first speaker, an output terminal of the second amplifier is connected to a terminal of a second polarity provided at the second speaker, and an output terminal of the third amplifier is connected to another terminal of the second polarity provided at the first speaker and to another terminal of the first polarity provided at the second speaker.

### BRIEF DESCRIPTION OF THE DRAWINGS

FIG. 1 is a block diagram showing an amplification circuit and an audio output equipment according to an embodiment of the invention.

FIG. 2 is a view to explain an operation to output stereo signals in the audio output equipment according to the embodiment.

FIG. 3 is an output waveform of the stereo signals which is produced in the amplification circuit according to the embodiment.

### DETAILED DESCRIPTION OF THE INVENTION

Hereafter, an embodiment of the invention will be described with reference to the drawings. In the drawings, the same numerals designate the same portions, respectively.

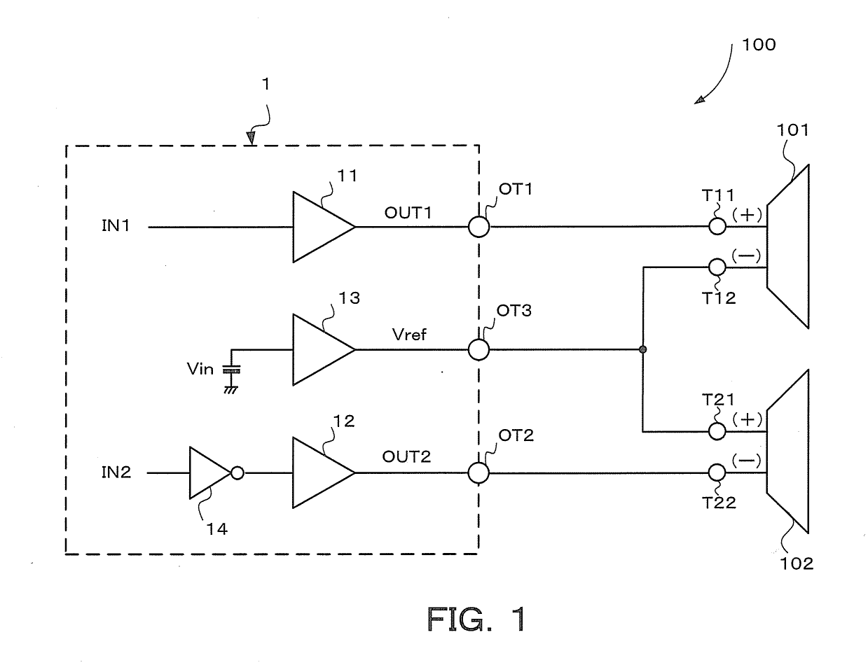

FIG. 1 is a block diagram showing an amplification circuit and an audio output equipment according to the embodiment.

As shown in FIG. 1, an amplification circuit 1 of the embodiment is provided with an amplifier 11. The amplifier 11 amplifies an inputted audio signal IN1 and outputs an amplified output signal OUT1 to an output terminal OT1. The amplification circuit 1 is provided with an inverter 14. The inverter 14 inverts an inputted audio signal IN2 and outputs an inverted audio signal.

The amplification circuit 1 is provided with amplifier 12 which amplifies the output signal of the inverter 14 and transmits an amplified output signal OUT2 to an output terminal OT2. The Amplification circuit 1 is further provided with an amplifier 13 which receives a predetermined voltage Vin and outputs a reference voltage, which corresponds to a central voltage of the amplitude of the output signal OUT1 and the output signal OUT2, to an output terminal OT3. The amplification circuit 1 is formed in a semiconductor chip.

An audio output equipment 100 is provided with the above amplification circuit 1 and speakers 101, 102 for two right and left channels respectively.

The output terminal OT1 of the amplification circuit 1 is connected to a terminal T11 of the speaker 101 which has a plus (+) polarity. The output terminal OT2 of the amplification circuit 1 is connected to a terminal T22 of the speaker 102 which has a minus (−) polarity. The output terminal OT3 of the amplification circuit 1 is connected to a terminal T12 of the speaker 101 which has the minus (−) polarity and to a terminal T21 of the speaker 102 which has the plus (+) polarity.

The amplifier 13 is connected to the minus (−) polarity terminal T12 of the speaker 101 and to the plus (+) polarity terminal T21 of the speaker 102. The amplifier 13 has a function to continue keeping a reference voltage Vref at a constant level by performing push-pull operation. The amplifier 13 absorbs current when the voltages of the terminal T11, T22 of the speaker 101, 102 increase. The amplifier 13 releases current when the voltages of the terminal T11, T22 of the speaker 101, 102 decrease.

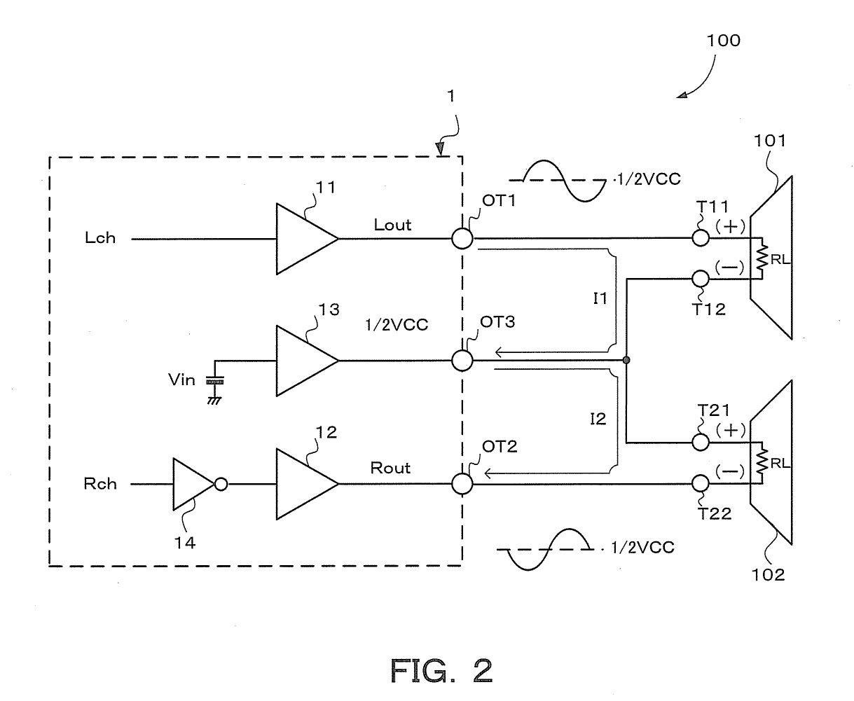

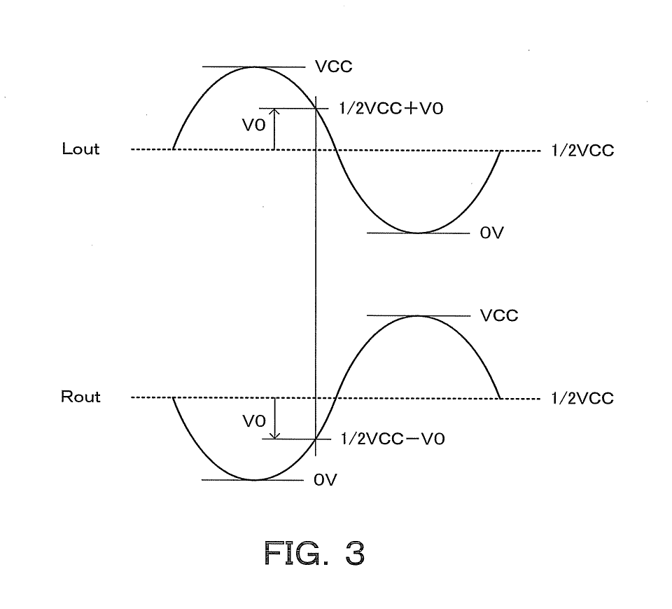

Operation of audio output equipment 100 according to the embodiment will be explained with reference to FIGS. 2 and 3. FIGS. 2 and 3 show operation when stereo signals are reproduced by the audio output equipment 100.

When stereo signals are reproduced, as shown in FIG. 2, an audio signal Lch of an L channel is inputted into the amplifier 11. An audio signal Rch of an R channel is inverted by the inverter 14. The inverted signal is inputted into the amplifier 12.

The reference voltage Vref, which is outputted from the amplifier 13, is expressed by the following formula, assuming that the amplitudes of an output signal Lout of the amplifier 11 and an output signal Rout of the amplifier 12 are equal to a power supply voltage VCC of the amplification circuit 1 or of the amplifiers 11 and 12.

Vref=½ VCC

A current I1, which flows in the speaker 101, is expressed by the following formula, when both of the load resistances of the speakers 101 and 102 are RL.

I1=(Lout−½ VCC)/RL

Further, a current I2 which flows in the speaker 102 is expressed by the following formula.

I2=(½ Vcc−Rout)/RL

Generally, a remarkable correlativity exists between the audio signal Lch of the L channel and the audio signal Rch of the R channel which constitute stereo signals respectively. The audio signal Lch contains first signal components, while the audio signal Rch contains second signal components. Lots of the first signal components are in-phase with Lots of the second signal components. The sound volumes based on the audio signals Lch, Rch need to be same substantially in order to have an acoustic image positioned at the center between the speakers 101, 102.

As the correlation exists, the inverted signal of the audio signal Rch may be deemed to be inputted to the amplifier 12 with the phase reversed to the audio signal Lch to be inputted to the amplifier 11.

Thus, as shown in FIG. 3, the output signal Lout and the output signal Rout are outputted from the amplifiers 11, 12 with th phases reversed to each other substantially.

The output signal Lout and the output signal Rout vary up and down and symmetrically with the reference voltage ½ VCC centered.

The level of the output signal Lout produced at a certain time is expressed by the following formula. V0 indicates a voltage level deviated from the reference voltage ½ VCC.

Lout=½ VCC+V0

The level of the output signal Rout produced at the same time is expressed by the following formula.

Rout=½ VCC−V0

A current I1, which flows in the speaker 101 at the time, is expressed by the following formula.

I1=(½ VCC+V0−½ VCC)/RL=V0/RL

A current I2, which flows in the speaker 102 at the time, is expressed by the following formula.

I2={½ VCC−(½ VCC−V0)}/RL=V0/RL

As a result, as shown below, the currents I1 and I2, which flow in the speakers 101, 102, are equal.

I1=I2

As mentioned above, currents of substantially the same value flow in the speakers 101, 102, when the audio signal Lch, Rch of the L and R channels, which constitute the stereo signals respectively, are in-phase substantially. A current value same as that being provided to the speaker 101 is provided to the speaker 102.

According to the embodiment, the amplification circuit 1 is composed of the three amplifiers 11 to 13 so that the power consumption in the amplification circuit 1 can be reduced by half, compared with a conventional audio output equipment which has a BTL connection system provided with four amplifiers.

Further, according to the embodiment, since the number of amplifiers decreases, the circuit scale of the amplification circuit 1 may be reduced so that the chip size of the amplification circuit can be smaller.

The audio output equipment of the embodiment does not need a capacitor which is required in a SEPP system. Thus, the structure of the audio output equipment is simplified.

A conventional audio output equipment of a BTL connection system may be exchanged for the audio output equipment of the embodiment easily, because the latter is compatible with the BTL connection system.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. An amplification circuit, comprising:
a first amplifier to amplify a first audio signal and to output a first output signal;
an inverter to invert a second audio signal and to output an inverted signal;
a second amplifier to amplify the inverted signal and to output a second output signal; and
a third amplifier to output a reference voltage corresponding to a central voltage of the amplitude of the first and the second output signals.

2. An amplification circuit according to claim 1, wherein the first, the second and the third amplifiers are formed on the same semiconductor chip.

3. An amplification circuit according to claim 1, the first and the second audio signals constitute stereo signals.

4. An amplification circuit according to claim 1, wherein the reference voltage is half a power supply voltage for the first and the second amplifiers.

5. An amplification circuit according to claim 4, wherein the first and the second output signals vary up and down with the reference voltage centered.

6. An amplification circuit according to claim 1, wherein the third amplifier is push-pull type.

7. An amplification circuit according to claim 1, wherein lots of the signal components of the first audio signal are in-phase with lots of the signal components of the second audio signal, and sound volumes based on the first and the second audio signals are same substantially.

8. An amplification circuit according to claim 1, further comprising first, second and third output terminals,
wherein the first output terminal receives the first output signal from the first amplifier and transmits the first output signal to a terminal of a first polarity provided at a first speaker, the second output terminal receives the second output signal from the second amplifier and transmits the second output signal to a terminal of a second polarity provided at a second speaker, and the third output terminal is given the reference voltage and transmits the reference voltage to another terminal of the second polarity provided at the first speaker and to another terminal of the first polarity provided at the second speaker.

9. An audio output equipment, comprising:
a first amplifier to amplify a first audio signal and to output a first output signal;
an inverter to invert a second audio signal and to output an inverted signal;
a second amplifier to amplify the inverted signal and to and to output a second output signal;
a third amplifier to output a reference voltage corresponding to a central voltage of the amplitude of the first and the second output signals; and
first and second speakers,
wherein an output terminal of the first amplifier is connected to a terminal of a first polarity provided at the first speaker, an output terminal of the second amplifier is connected to a terminal of a second polarity provided at the second speaker, and an output terminal of the third amplifier is connected to another terminal of the second polarity provided at the first speaker and to another terminal of the first polarity provided at the second speaker.

10. An audio output equipment according to claim 9, wherein the first, the second and the third amplifiers are formed on the same semiconductor chip.

11. An audio output equipment according to claim 9, the first and the second audio signals constitute stereo signals.

12. An audio output equipment according to claim 9, wherein the reference voltage is half a power supply voltage for the first and the second amplifiers.

13. An audio output equipment according to claim 12, wherein the first and the second output signals vary up and down with the reference voltage centered.

14. An audio output equipment according to claim 9, wherein the third amplifier is push-pull type.

15. An audio output equipment according to claim 9, wherein lots of the signal components of the first audio signal are in-phase with lots of the signal components of the second audio signal, and sound volumes based on the first and the second audio signals are same substantially.

16. An audio output equipment according to claim 9, further comprising first, second and third output terminals,
wherein the first output terminal receives the first output signal from the first amplifier and transmits the first output signal to a terminal of a first polarity provided at a first speaker, the second output terminal receives the second output signal from the second amplifier and transmits the second output signal to a terminal of a second polarity provided at a second speaker, and the third output terminal is given the reference voltage and transmits the reference voltage to another terminal of the second polarity provided at the first speaker and to another terminal of the first polarity provided at the second speaker.
